(19) United States
(12) Patent Application Publication
(10) Pub. No.: US 2026/0255750 A1
(43) Pub. Date: Aug. 27, 2026

(54) DISPLAY PANEL AND DISPLAY APPARATUS

(71) Applicants: Beijing BOE Technology Development Co., Ltd., Beijing (CN); BOE Technology Group Co., Ltd., Beijing (CN)

(72) Inventors: Wenchao HAN, Beijing (CN); Dacheng ZHANG, Beijing (CN); Xue DONG, Beijing (CN); Wei SUN, Beijing (CN); Zhongyuan WU, Beijing (CN)

(21) Appl. No.: 18/860,635

(22) PCT Filed: Jan. 2, 2024
(86) PCT No.: PCT/CN2024/070038

§ 371 Date: Oct. 26, 2024

(30) Foreign Application Priority Data
Jan. 19, 2023 (CN) 202310107945.2

(51) Int. Cl. H10H 29/32; H10F 39/00; H10F 39/12; H10H 29/39; H10H 29/49; H10H 29/85; H10H 29/855

(52) U.S. Cl. CPC H10H 29/32; H10F 39/197; H10F 39/8053; H10F 39/8057; H10H 29/49; H10H 29/8517; H10H 29/8552; H10H 29/39

(57) ABSTRACT

Provided in the embodiments of the present disclosure are a display panel and a display apparatus. The display panel comprises a base substrate, the base substrate being divided into a display area and a peripheral area surrounding the display area; and a driving function layer, located on the base substrate, the driving function layer comprising: a photosensitive transistor located in the peripheral area and a plurality of pixel circuit transistors located in the display area. The peripheral area comprises a first N-well region, the first N-well region surrounding a gate of the photosensitive transistor. The display area comprises a second N-well region, the second N-well region overlapping gates of the pixel circuit transistors. The overlapping area of the second N-well region and the gates of the pixel circuit transistors is larger than the overlapping area of the first N-well region and the gate of the photosensitive transistor.

### CROSS-REFERENCE TO RELATED APPLICATIONS

The present application is a U.S. National Phase Entry of International Application No. PCT/CN2024/070038 having an international filing date of Jan. 2, 2024, which claims priority to the Chinese patent application No. 202310107945.2, filed to the CNIPA on Jan. 19, 2023, the contents of which should be interpreted as being incorporated into the present application by reference.

### TECHNICAL FIELD

The present disclosure relates to the field of display technologies, and specifically to a display panel and a display apparatus.

### BACKGROUND

At present, the tracking and detection of human pupils in the display technology mainly includes the following ways: 1. acquiring high-resolution images through external camera modules, and detecting and analyzing the images to determine the position of eyeballs; 2. adding a separate sensor film layer and arranging multiple sensor elements on the film layer; 3. providing sensor elements arranged in an array between the pixel units in the display region of the display panel to detect the position of the eyeballs. However, none of the above solutions can meet requirements of the narrow bezel and low power consumption of the display panel while ensuring the accuracy of human pupil detection.

### SUMMARY

Embodiments of the present disclosure provide a display panel and a display apparatus.

In a first aspect, a display panel is provided in an embodiment of the present disclosure, which includes: a substrate divided into a display region and a peripheral region surrounding the display region; and a drive function layer located on the substrate, wherein the drive function layer includes: a photosensitive transistor located in the peripheral region and multiple pixel circuit transistors located in the display region.

The peripheral region includes a first N-well region surrounding a gate electrode of the photosensitive transistor, and the display region includes a second N-well region overlapping with a gate electrode of a pixel circuit transistor, and an overlapping area of the second N-well region and the gate electrode of the pixel circuit transistor is larger than an overlapping area of the first N-well region and the gate electrode of the photosensitive transistor.

In some embodiments, the photosensitive transistor further includes a P-well region corresponding to the first N-well region, and the first N-well region surrounds the P-well region.

In some embodiments, an area of the P-well region surrounded by the first N-well region is larger than a channel area of the pixel circuit transistor.

In some embodiments, a size of the photosensitive transistor is larger than a size of the pixel circuit transistor.

In some embodiments, the drive function layer further includes a first deep N-well region located on a side of the first N-well region close to the substrate, and a thickness of the first deep N-well region is greater than a thickness of the first N-well region or the second N-well region.

In some embodiments, the display panel further includes:
a light emitting element layer located on a side of the drive function layer away from the substrate and located in the display region, and the light emitting element layer includes multiple light emitting elements, and the light emitting elements are electrically connected to corresponding pixel circuit transistors.

In some embodiments, the photosensitive transistor is configured to receive non-visible light in a preset wavelength range.

In some embodiments, the photosensitive transistor includes a bipolar junction transistor.

In some embodiments, the light emitting element includes: a first electrode, a light emitting layer, and a second electrode, the first electrode is electrically connected to a corresponding pixel circuit transistor; the drive function layer further includes: a voltage transmission wiring located in the peripheral region and electrically connected to the second electrode; and the photosensitive transistor is located on a side of the voltage transmission wiring away from the display region.

In some embodiments, an orthographic projection of any metal pattern located on the photosensitive transistor away from the substrate on the photosensitive transistor does not overlap with a region where the first N-well region surrounds the P-well region.

In some embodiments, the display panel further includes: a color filter layer located on a side of the light emitting element layer away from the substrate, wherein the color filter layer includes a first light filter portion and a first black matrix that are located in the peripheral region.

At least one first light transmitting region corresponding to the photosensitive transistor is provided on the first black matrix, an orthographic projection of the first light transmitting region on the substrate overlaps with a region where the first N-well region of the corresponding photosensitive transistor surrounds the P-well region, the first light filter portion is located in the first light transmitting region, and the first light filter portion is configured to filter visible light.

In some embodiments, an orthographic projection of the first black matrix on the substrate does not overlap with an orthographic projection of a region where the first N-well region of the corresponding photosensitive transistor surrounds the P-well region on the substrate.

In some embodiments, the first light filter portion at least includes a first filter pattern and a second filter pattern disposed in a stack, the first filter pattern is configured to filter light in a wavelength range of a visible light wavelength range except a first wavelength range, the second filter pattern is configured to filter light in a wavelength range of the visible light wavelength range except a second wavelength range, and there is no overlap between the first wavelength range and the second wavelength range.

In some embodiments, light of the first wavelength range is red light and light of the second wavelength range is blue light;
the first light filter portion further includes a third filter pattern stacked with the first filter figure and the second filter pattern, and the third filter pattern is configured to be able to filter light of a color except green light among visible light.

In some embodiments, the color filter layer further includes: a second black matrix and multiple color filter patterns located in the display region, the multiple color filter patterns include: at least one fourth filter pattern, at least one fifth filter pattern, and at least one sixth filter pattern.

The fourth filter pattern is configured to be capable of filtering light of other colors other than red light in visible light, and the fourth filter pattern is made of the same material as the first filter pattern.

The fifth filter pattern is configured to be capable of filtering light of other colors other than blue light in visible light, and the fifth filter pattern is made of the same material as the second filter pattern.

The sixth filter pattern is configured to be capable of filtering light of other colors other than green light in visible light, and the sixth filter pattern is made of the same material as the third filter pattern.

The second black matrix includes multiple second light transmitting regions corresponding to the light emitting elements, an orthographic projection of a second light transmitting region on the substrate overlaps with an orthographic projection of a light emitting layer of a corresponding light emitting element on the substrate, and a corresponding color filter pattern is provided in the second light transmitting region.

In some embodiments, the first filter portion is configured to allow infrared light to pass through.

In some embodiments, the display panel further includes: a light converging layer located on a side of the color filter layer away from the substrate, wherein the light converging layer includes a first converging lens located in the peripheral region and corresponds to the photosensitive transistor, and a second converging lens located in the display region and corresponds to the light emitting element.

An orthographic projection of the first converging lens on the substrate covers a region where the first N-well region of the corresponding photosensitive transistor surrounds the P-well region.

An orthographic projection of the second converging lens on the substrate covers an orthographic projection of the light emitting layer of the corresponding light emitting element on the substrate.

A focal length of the first converging lens is greater than a focal length of the second converging lens.

In some embodiments, the peripheral region includes: a first peripheral sub-region arranged in a first direction with the display region, and multiple photosensitive transistors arranged in a second direction are provided in the first peripheral sub-region.

The photosensitive transistors in the first peripheral sub-region are in one-to-one correspondence with the first converging lenses; alternatively, all photosensitive transistors in the first peripheral sub-region correspond to a same first converging lens.

In some embodiments, the photosensitive transistors in the first peripheral sub-region are in one-to-one correspondence with the first converging lenses; the first converging lens is a cylindrical lens, and an extension direction of a central axis of the cylindrical lens is perpendicular to a plane on which the substrate is located; alternatively, the first converging lens is a first convex lens, and an extension direction of the first convex lens is parallel to the first direction.

In some embodiments, all photosensitive transistors in the first peripheral sub-region correspond to the same first converging lens; and the first converging lens is a second convex lens, and an extension direction of the second convex lens is parallel to the second direction.

In some embodiments, the display panel further includes a protection layer.

In some embodiments, a light shield layer is provided between the protection layer and the light converging layer, and a third light transmitting region is formed in the light shield layer at a position of the display region.

The light shield layer covers the peripheral region and is configured to shield visible light and allow non-visible light within a preset wavelength range to pass through; alternatively, the light shield layer is provided with a fourth light transmitting region in a position of the light shield layer corresponding to a position where the first N-well region of the photosensitive transistor surrounds the P-well region, and a second light filter portion is provided in the fourth light transmitting region, and the second light filter portion is configured to filter visible light.

In a second aspect, an embodiment of the present disclosure further provides a display apparatus, including the aforementioned display panel.

### BRIEF DESCRIPTION OF DRAWINGS

The drawings are used for providing a further understanding of the present disclosure and constitute a part of the specification, and are used for explaining the present disclosure together with the following specific implementations but do not constitute limitations on the present disclosure. In the drawings:

FIG. 1 is a schematic diagram of a structure of a display panel according to an embodiment of the present disclosure.

FIG. 2 is a planar diagram of a structure of a photosensitive transistor according to an embodiment of the present disclosure.

FIG. 3 is a schematic cross-sectional view taken along line AA in FIG. 2.

FIG. 4 is a planar diagram of a structure of a pixel circuit transistor according to an embodiment of the present disclosure.

FIG. 5 is a top view of a structure of a pixel circuit transistor according to an embodiment of the present disclosure.

FIGS. 6 to 8 are schematic diagrams of structures of a first converging lens according to an embodiment of the present disclosure.

DESCRIPTION OF REFERENCE SIGNS IN THE DRAWING
display region AA, peripheral region NA, photosensitive region P;
substrate 1, drive function layer 2, light emitting element layer 3, encapsulation layer 4, first planarization layer 5, color filter layer 6, second planarization layer 7, light converging layer 8, adhesive layer 9, protection layer 10, light shield layer 11;
first light filter portion 61, first black matrix 62, color filter pattern 63, second black matrix 64, first filter pattern 611, second filter pattern 612, third filter pattern 613, fourth filter pattern 631, fifth filter pattern 632, sixth filter pattern 633, first light transmitting region 6a, second light transmitting region 6b; first converging lens 81, second converging lens 82; light shield layer 101, third light transmitting region 11a, fourth light transmitting region 11b, second light filter portion 111;
photosensitive transistor 21: first P-type substrate P-sub1, first deep N-well region DNW1, first shallow N-well region Nwell1, shallow P-well region Pwell, first N-well region N+1, P-well region P+, barrier structure B, insulating layer 210;
pixel circuit transistor 22: second P-type substrate P-sub2, second deep N-well region DNW2, second shallow N-well region Nwell2, second N-well region N+2, gate electrode region GT, barrier structure B, gate insulating layer GI.

### DETAILED DESCRIPTION

Specific implementations of the present disclosure are described in detail below with reference to the accompanying drawings. It should be understood that the specific implementations described herein are only intended to illustrate and explain the present disclosure and are not intended to limit the present disclosure.

In order to make objectives, technical solutions and advantages of the embodiments of the present disclosure more clear, the technical solutions of the embodiments of the present disclosure will be clearly and completely described below with reference to the drawings of the embodiments of the present disclosure. Apparently, the described embodiments are a part of the embodiments of the present disclosure, not all of the embodiments. Based on the described embodiments of the present disclosure, all other embodiments obtained by those of ordinary skills in the art without paying any inventive effort are within the protection scope of the present disclosure.

Unless otherwise defined, technical terms or scientific terms used in the embodiments of the present disclosure shall have common meanings understood by those with ordinary skills in the art to which the present disclosure pertains. The term “first”, “second” and similar terms used in the present disclosure do not indicate any order, quantity, or importance, but are used only for distinguishing different components. Likewise, wording such as “include”, “contain” or the like means that elements or objects before the wording cover elements or objects listed after the wording and their equivalents, but do not exclude other elements or objects. “Connect”, “couple”, or similar words are not limited to a physical or mechanical connection, but may include an electrical connection, whether direct or indirect. “Upper”, “lower”, “left”, and “right”, etc., are used for representing a relative positional relationship, and when an absolute position of a described object is changed, the relative positional relationship may also be correspondingly changed.

At present, the tracking and detection of human pupils in the display technology mainly includes the following ways: 1. acquiring high-resolution images through external camera modules, and detecting and analyzing the images to determine the position of eyeballs; 2. adding a separate sensor film layer and arranging multiple sensor elements on the film layer; 3. providing sensor elements arranged in an array between the pixel units in the display region AA of the display panel to detect the position of the eyeballs. In view of the above solutions, both solutions of providing a camera module and providing a separate sensor film layer will increase the area or thickness of the display module, which is not conducive to setting a narrow bezel, and increases the manufacturing cost. In the way in which the sensor array is built in the display region AA, on the one hand, the light source cannot be effectively filtered, and the light emitted by the light emitting elements will cause interference to the sensor elements, resulting in large noise and low accuracy of the sensor elements; on the other hand, the sampling time is long, which affects the normal display effect of the display panel and increases the power consumption of the display module.

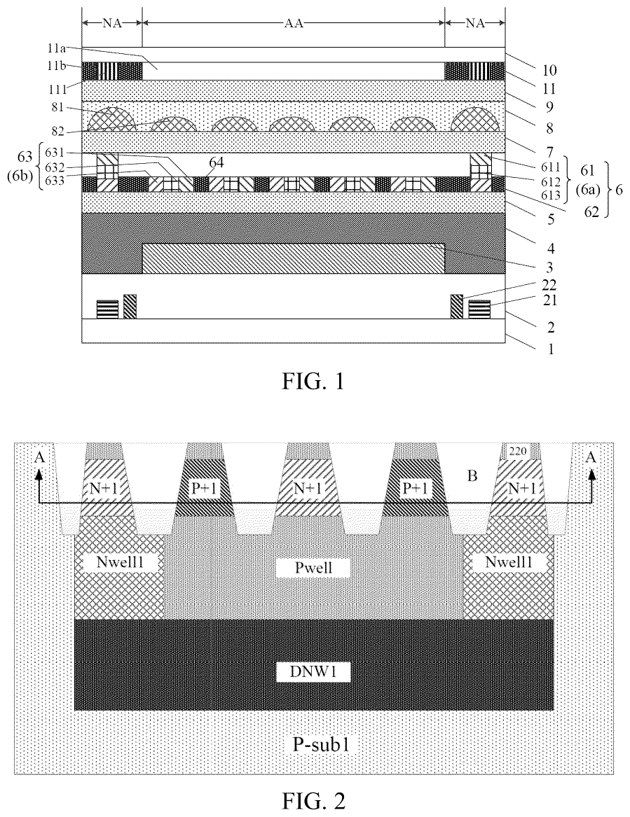

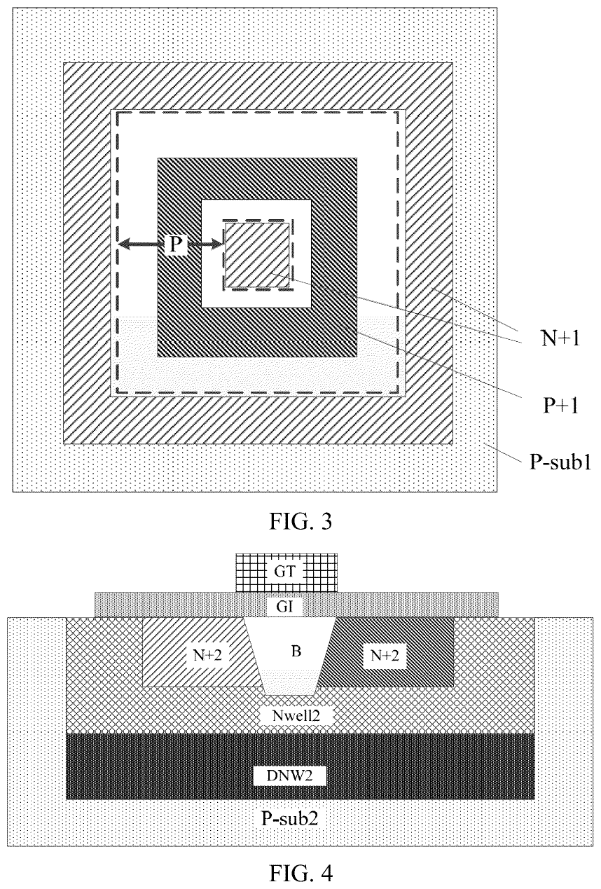

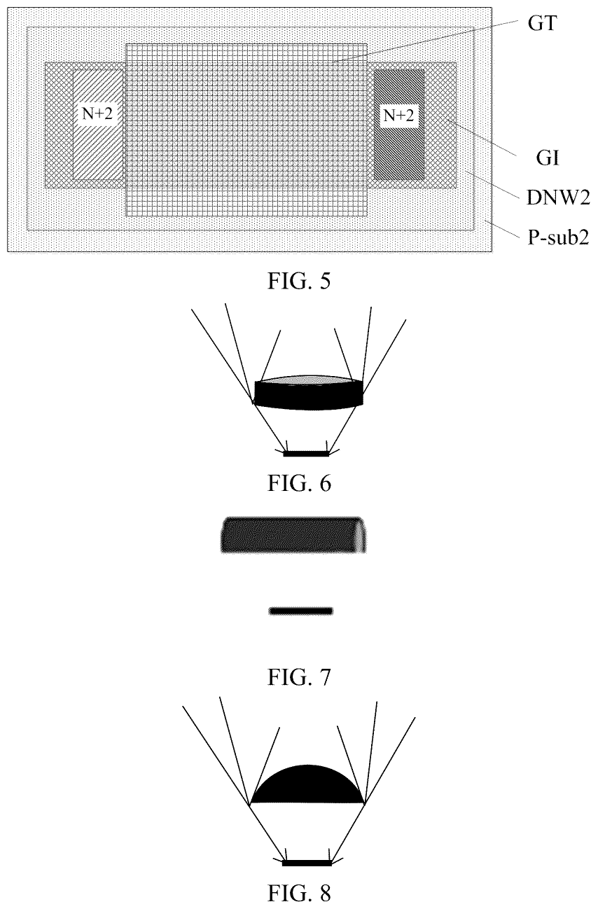

To solve at least one of the above technical problems, an embodiment of the present disclosure provides a display panel. FIG. 1 is a schematic diagram of a structure of a display panel according to an embodiment of the present disclosure. FIG. 2 is a planar diagram of a structure of a photosensitive transistor 21 according to an embodiment of the present disclosure. FIG. 3 is a schematic cross-sectional view taken along line AA in FIG. 2. FIG. 4 is a planar diagram of a structure of a pixel circuit transistor 22 according to an embodiment of the present disclosure. FIG. 5 is a top view of a structure of a pixel circuit transistor according to an embodiment of the present disclosure.

As shown in FIGS. 1 to 5, the display panel includes a substrate 1 and a drive function layer 2, wherein, the substrate 1 is divided into a display region AA and a peripheral region NA surrounding the display region AA. The drive function layer 2 is located on the substrate 1, and the drive function layer 2 includes: a photosensitive transistor 21 located in the peripheral region NA and multiple pixel circuit transistors 22 located in the display region AA. The peripheral region NA of the display panel includes a first N-well region N+1 surrounding a gate electrode of the photosensitive transistor 21, and the display region AA includes a second N-well region N+2 overlapping a gate electrode of the pixel circuit transistor 22; and an overlapping area between the second N-well region and the gate electrode of the pixel circuit transistor is larger than an overlapping area between the first N-well region and the gate electrode of the photosensitive transistor.

In the display panel provided by the embodiment of the present disclosure, the photosensitive transistor 21 is integrated in the drive function layer 2. Compared with the way of adding external camera module or sensor film layer in the related art, the thickness or area of the display panel is not increased, and the manufacturing cost is reduced. At the same time, the photosensitive transistor 21 is located in the peripheral region NA, so that the light emitted by the light emitting element is avoided from interfering to the photosensitive transistor 21. Based on this, the display panel detects the pupil position through the photosensitive transistor 21, and there is no need to acquire high-resolution images, thus reducing the power consumption of the display panel.

It should be noted that the first N-well region and the gate electrode of the photosensitive transistor may or may not overlap, and FIG. 2 shows only a structure in which the first N-well region and the gate electrode of the photosensitive transistor do not overlap with each other. When there is an overlap thereof, an overlapping area of the first N-well region and the gate electrode of the photosensitive transistor is smaller than an overlapping area of the second N-well region and the gate electrode of the pixel circuit transistor.

In some embodiments, the photosensitive transistor 21 is configured to receive non-visible light in a preset wavelength range. That is, the photosensitive transistor 21 tracks the pupil position by detecting the change of non-visible light, thereby reducing the interference of visible light and improving the detection accuracy.

Here, the above-described non-visible light may be any one of infrared light, ultraviolet light, X-rays, and y-rays, which are related to the device properties of the photosensitive transistor 21, and the embodiments of the present disclosure are not limited thereto.

In some embodiments, the photosensitive transistor 21 may be a bipolar junction transistor.

In some embodiments, as shown in FIGS. 2 and 3, the photosensitive transistor 21 may include: a first P-type substrate P-sub1, a first deep N-well region DNW1, a first shallow N-well region Nwell1, a shallow P-well region Pwel1, a first N-well region N+1, a P-well region P+, a barrier structure B, and an insulating layer 220.

Specifically, the first shallow N-well region and the shallow P-well region Pwell are located on one side of the first P-type substrate P-sub1, and the first shallow N-well region Nwell1 surrounds the shallow P-well region Pwel1, a first shallow trench isolation is formed between the first shallow N-well region Nwell1 and the shallow P-well region Pwell, and a second shallow trench isolation is formed in the shallow P-well region Pwell. A first P+ doped region is formed in the shallow P-well region Pwell between the first shallow trench isolation and the second shallow trench isolation, a first N+ doped region is formed in the first shallow N-well region Nwell1 on a side of the first shallow trench isolation, a second N+ doped region is formed in the shallow P-well region Pwell on the other side of the second shallow trench isolation. A third electrode and a barrier structure B in parallel are formed on the second N+ doped region, a fourth electrode is formed on the first P+ doped region, and a fifth electrode is formed on the first N+ doped region. Herein, a planarization layer is deposited before the ion implantation process, then N-type ion implantation is performed, then a metal silicide barrier layer is deposited and the barrier structure B is etched, and finally the third electrode to the fifth electrode are formed.

The third electrode is an emitter of the photosensitive transistor, the fourth electrode is a base of the photosensitive transistor, and the fifth electrode is a collector of the photosensitive transistor. Specifically, an N-type heavily doped region is formed as a emitting region and a collecting region of a transistor, that is, a first N-well region N+1, by implantation of N-type ions, and a P-type heavily doped region is formed as a base region of the transistor, that is, a P-well region P+, by implantation of P-type ions.

It should be understood that the first P-type substrate P-sub1 may be a silicon-based substrate on which ion implantation cannot be directly performed to form an electrode, and thus a first deep N-well region DNW1 is further provided between the first shallow N-well region/shallow P-well region and the first P-type substrate P-sub1, to provide a protective effect on the substrate structure.

Further, from the above description, it can be seen that a first P+-doped region is formed in the shallow P-well between the first shallow trench isolation and the second shallow trench isolation, and a transistor base region is formed on the first P+-doped region by implanting P-type ions. For the bipolar junction transistor, N-type high doping is typically performed in the emitting region so that electrons injected from the emitting region into the base region form a relatively high electron concentration gradient in the base region when the emitter junction is forward biased. The base region is designed so thin that only a small portion of the electrons injected into the base region recombine with the majority carriers, that is, electron holes, to form the base current. That is, since the base region of the photosensitive transistor can form carrier movement to form the base current, the base region may be regarded as the photosensitive region P of the photosensitive transistor, that is, a region where the P-well region P+ is surrounded by the first N-well region N+1.

In some embodiments, as shown in FIGS. 4 and 5, pixel circuit transistor 22 may include: a second P-type substrate P-sub2, a second deep N-well region DNW2, a second shallow N-well region Nwell2, a second N-well region N+2, a gate electrode region GT, a barrier structure B, and a gate insulating layer GI.

In an embodiment of the present disclosure, the pixel circuit transistor 22 takes a top-gate NMOS as an example, and both source and drain electrodes are formed by implanting N-type ions and doping. Specifically, a second deep N-well region DNW2 is formed on the second P-type substrate P-sub2, a second shallow N-well region Nwell2 is formed on the second deep N-well region DNW2, and a source electrode connection portion, a channel portion, and a drain electrode connection portion are formed in parallel on the second shallow N-well region Nwell2. Specifically, both the source electrode connection portion and the drain electrode connection portion may be implanted with an N-type impurity doped with a higher impurity concentration than that of the channel portion, that is, the second N-well region N+2 may be formed to form the source electrode and the drain electrode. The channel portion faces a gate electrode of the pixel circuit transistor 22, and when the voltage signal applied by the gate electrode reaches a certain value, a carrier path is formed in the channel portion, and the source and drain electrodes are turned on. Herein, a gate insulating layer GI, which may be a silicon oxynitride material, is further provided between the gate electrode and the channel portion, and the gate electrode may be formed by depositing a metal material, such as metal aluminum, on the gate insulating layer GI, which is not limited to the embodiment of the present disclosure.

In some embodiments, an area of the P-well region P+ surrounded by the first N-well region N+1 is larger than a channel area of the pixel circuit transistor 22.

It should be understood that the bipolar junction transistor has a larger channel area, that is, a larger area perpendicular to the carrier movement direction, compared to other types of transistors, so that the area of the photosensitive region P of the bipolar junction transistor is larger during detection, and thus the detection sensitivity can be higher. As shown in FIG. 3, a region in which the first N-well region N+1 surrounds the P-well region P+ is a photosensitive region P of the bipolar junction transistor.

In some embodiments, a size of the photosensitive transistor 21 is larger than a size of the pixel circuit transistor 22. Specifically, a size of the photosensitive transistor 21 in a third direction is larger than a size of the pixel circuit transistor 22 in the third direction. The third direction may be any direction perpendicular to the direction of the normal line of the display panel. For example, the size of the photosensitive transistor may be 5-100 μm, and larger than the size of the pixel circuit transistor, which may be 1-5 μm.

In addition, in the preparation process of the display panel, the first P-type substrate P-sub1 and the second P-type substrate P-sub2 may be connected as an integrated structure, and both may be formed in the same preparation process; the first deep N-well region DNW1 and the second deep N-well region DNW2 may be located on the same film layer and formed by the same mask preparation; the first shallow N-well region Nwell1 and the second shallow N-well region Nwell2 may be located on the same film layer and formed by the same mask preparation; the first N-well region N+1 and the second N-well region N+2 may be located on the same film layer and formed by the same mask preparation. Moreover, the barrier structures B located in the photosensitive transistor and the pixel circuit transistor may also be formed and etched in the same preparation process. Based on the above structure, the preparation process can be greatly reduced, which is beneficial to reducing the preparation cost.

In some embodiments, as shown in FIG. 1, the display panel further includes a light emitting element layer 3 located on a side of the drive function layer 2 away from the substrate 1 and located in the display region AA. The light emitting element layer 3 includes multiple light emitting elements (not shown in the figure), and the light emitting element is electrically connected to a corresponding pixel circuit transistor 22, and the pixel circuit transistor 22 is configured to provide electrical signals to the corresponding light emitting element.

In some embodiments, the light emitting element includes: a first electrode, a light emitting layer, and a second electrode, the first electrode is connected to a corresponding pixel circuit transistor 22; the drive function layer 2 further includes: a voltage transmission wiring located in the peripheral region NA and electrically connected to the second electrode; and the photosensitive transistor 21 is located on a side of the voltage transmission wiring away from the display region AA. Therefore, there is a certain distance between the photosensitive transistor 21 located in the peripheral region NA and the pixel circuit transistor 22 located in the display region AA, which facilitates the light shield processing of the photosensitive transistor 21, and at the same time, the light emitted by the light emitting element in the display region AA does not interfere to the photosensitive transistor 21.

It should be understood that the above-described voltage transmission wiring surrounds the display region AA in an annular shape, and is configured to provide a voltage to the first electrode, and can also be used to shield an external electric field to avoid generation of interference signals affecting the display effect of the display panel.

In some embodiments, an orthographic projection of any metal pattern located on a side of the photosensitive transistor 21 away from the substrate 1 on the photosensitive transistor 21 does not overlap with the photosensitive region P. That is, in the film layer above the photosensitive transistor 21, the metal pattern does not block the photosensitive region P, so as to avoid affecting the reception of non-visible light by the photosensitive transistor 21, and ensure the detection accuracy thereof.

It should be noted that the photosensitive transistor 21 is configured with a connection wiring, and the above-described “any metal pattern located on a side of the photosensitive transistor 21 away from the substrate 1” does not include the connection wiring of the photosensitive transistor 21.

In some embodiments, as shown in FIG. 1, the display panel further includes: a color filter layer 6 located on a side of the light emitting element layer 3 away from the substrate 1, and the color filter layer 6 includes a first light filter portion 61 and a first black matrix 62 that are located in the peripheral region NA. The first black matrix 62 is provided with at least one first light transmitting region 6a corresponding to the photosensitive transistor 21, an orthographic projection of the first light transmitting region 6a on the substrate 1 overlaps with the photosensitive region P, which is a region where the first N-well region N+1 of the corresponding photosensitive transistor 21 surrounds the P-well region P+, and the first light filter portion 61 is located in the first light transmitting region 6a, and the first light filter portion 61 is configured to filter visible light.

Since the first filter region overlaps with the photosensitive region P, at least a portion of the photosensitive region P corresponding to the photosensitive transistor 21 that overlaps with the first filter region can receive invisible light, and thereby further detect the pupil position.

In some embodiments, the photosensitive transistor 21 in the embodiment of the present disclosure is configured to detect infrared light to determine the pupil position, and thus, the first light filter portion 61 is configured to allow the infrared light to pass through. In some other examples, the sensed light of the photosensitive transistor 21 may be non-visible light other than infrared light, and then the first light filter portion 61 matches with the device properties of the photosensitive transistor 21, and is configured to allow the sensed light corresponding to the photosensitive transistor 21 to pass through.

In some embodiments, as shown in FIG. 1, an orthographic projection of the first black matrix 62 on the substrate 1 does not overlap with an orthographic projection of the photosensitive region P of the corresponding photosensitive transistor 21 on the substrate 1. Therefore, on the one hand, the arrangement of the first black matrix 62 can shield visible light to avoid interference to the photosensitive transistor 21, on the other hand, it does not shield the photosensitive region P, and does not affect the reception of non-visible light by the photosensitive transistor 21, which is beneficial to improving the detection accuracy of the photosensitive transistor 21.

In some embodiments, as illustrated in FIG. 1, the first light filter portion 61 at least includes a first filter pattern 611 and a second filter pattern 612 disposed in a stacked manner, the first filter pattern 611 is configured to filter light in a wavelength range of the visible light wavelength range except a first wavelength range, the second filter figure 612 is configured to filter light in a wavelength range of the visible light wavelength range except a second wavelength range, and there is no overlap between the first wavelength range and the second wavelength range. Since there is no overlap between the first wavelength range and the second wavelength range, visible light can be completely filtered after two filterings by the first light filter portion 61.

In some embodiments, a first wavelength range may be 630-780 nm, i.e., the first filter pattern 611 is configured to be able to filter other color light in visible light except red light; and the second wavelength range may be 420-470 nm, i.e., the second filter pattern 612 is configured to be able to filter other color light in visible light except blue light. The first light filter portion 6′ further includes a third filter pattern 613 stacked with the first filter pattern 611 and the second filter pattern 612, and the third filter pattern 613 is configured to be able to filter light of a color other than green light among visible light.

It should be noted that, when the first light filter portion 61 includes the first filter pattern 611 and the second filter pattern 612, the embodiment of the present disclosure does not limit the stacking order of the two. The first filter pattern 611 may be provided on a side of the second filter pattern 612 away from the substrate 1, or the first filter pattern 611 may be provided on a side of the second filter pattern 612 close to the substrate 1. When the first light filter portion 61 further includes the third filter pattern 613, the stacking position of the third filter pattern 613 is also not limited in the embodiment of the present disclosure.

In some embodiments, as shown in FIG. 1, the color filter layer 6 further includes: a second black matrix 64 and multiple color filter patterns 63 that are located in the display region AA. The multiple color filter patterns 63 include: at least one fourth filter pattern 631, at least one fifth filter pattern 632, and at least one sixth filter pattern 633. The fourth filter pattern 631 is configured to be capable of filtering light of other colors in visible light except red light, and the fourth filter pattern 631 is made of the same material as the first filter pattern 611; the fifth filter pattern 632 is configured to be capable of filtering light of other colors in visible light except blue light, the fifth filter pattern 632 is made of the same material as the second filter pattern 612; and the sixth filter pattern 633 is configured to be capable of filtering light of other colors in visible light except green light, and the sixth filter pattern 633 is made of the same material as the third filter pattern 613.

The second black matrix 64 includes multiple second light transmitting regions 6b corresponding to the light emitting elements, an orthographic projection of the second light transmitting region 6b on the substrate 1 overlaps with an orthographic projection of a light emitting layer of the corresponding light emitting element on the substrate 1, and a corresponding color filter pattern 63 is provided in the second light transmitting region 6b.

It should be understood that the materials of the fourth filter pattern 631 and the first filter pattern 611 are the same, and thus both can be formed under the same preparation process, and similarly, the fifth filter pattern 632 and the second filter pattern 612, and the sixth filter pattern 633 and the third filter pattern 613 can be formed under the same preparation process; and the first black matrix 62 and the second black matrix 64 may be connected as an integrated structure. Therefore, the first light filter portion 61 and the first black matrix 62 may be formed without increasing the process, and the preparation process and the preparation cost can be saved.

In some embodiments, as shown in FIG. 1, the display panel further includes: a light converging layer 8 located on a side of the color filter layer 6 away from the substrate 1. The light converging layer 8 includes a first converging lens 81 and a second converging lens 82, the first converging lens 81 is located in the peripheral region NA and corresponds to the photosensitive transistor 21, and the second converging lens 82 is located in the display region AA and corresponds to the light emitting element. An orthographic projection of the first converging lens 81 on the substrate 1 covers the photosensitive region P of the corresponding photosensitive transistor 21; and an orthographic projection of the second converging lens 82 on the substrate 1 covers an orthographic projection of the light emitting layer of the corresponding light emitting element on the substrate 1, wherein a focal length of the first converging lens 81 is larger than a focal length of the second converging lens 82.

As shown in FIG. 1, firstly, the first converging lens 81 and the second converging lens 82 are located in the same layer, secondly, the first converging lens 81 is configured to converge non-visible light and emit it to the photosensitive transistor 21, and the second converging lens 82 is configured to converge visible light and emit it to the light emitting element, and the photosensitive transistor 21 is located in the drive function layer 2 on a side of the light emitting element close to the substrate 1. That is, since a distance between the first converging lens 81 and the corresponding photosensitive transistor 21 on the normal line of the substrate 1 is larger than a distance between the second converging lens 82 and the corresponding light emitting element on the normal line of the substrate 1, the focal length of the first converging lens 81 is set to be larger than the focal length of the second converging lens 82, to ensure a good condensing effect.

In addition, the first converging lens 81 and the second converging lens 82 may be formed in the same preparation process, or a preparation process of the first converging lens 81 may be separately added, and the embodiments of the present disclosure are not limited thereto.

In some embodiments, the peripheral region NA of the display panel includes a first peripheral sub-region (not shown in the figure), the first peripheral sub-region and the display region AA are arranged in the first direction, and multiple photosensitive transistors 21 arranged in the second direction are provided in the first peripheral sub-region.

It should be noted that the peripheral region NA of the display panel may include one first peripheral sub-region or multiple first peripheral sub-regions, that is, the photosensitive transistor 21 may be provided on a boundary of a side of the display region AA, for example, above the display region AA; or may be located on multiple boundaries of the display region AA, for example, on the left and right sides of the display region AA, and the embodiments of the present disclosure are not limited thereto.

The photosensitive transistors 21 are arranged in an array in the first peripheral sub-region along the second direction, wherein a length of the first peripheral sub-region may be L, and a size of the photosensitive transistors 21 may be X; then the number of the photosensitive transistors 21 located in the first peripheral sub-region may be L/X rounded. And, a width of the photosensitive transistor 21 in the first peripheral sub-region, that is, a size thereof in the first direction is less than 0.1 mm, which can meet the narrow bezel requirement of the display panel.

The photosensitive transistors 21 in the first peripheral sub-region are in one-to-one correspondence with the first converging lenses 81; alternatively, all of the photosensitive transistors 21 in the first peripheral sub-region correspond to the same first converging lens 81.

FIGS. 6 to 8 are schematic diagrams of structures of the first converging lens 81 according to the embodiment of the present disclosure. In some embodiments, when the photosensitive transistors 21 in the first peripheral sub-region are in one-to-one correspondence with the first converging lenses 81, as shown in FIG. 6, the first converging lens 81 is a cylindrical lens, and an extension direction of the central axis of the cylindrical lens is perpendicular to a plane on which the substrate 1 is located. Alternatively, as shown in FIG. 7, the first converging lens 81 is a first convex lens, and an extension direction of the first convex lens is parallel to the first direction, that is, parallel to a direction in which the display region AA points to the first peripheral sub-region.

In some other embodiments, when all the photosensitive transistors 21 in the first peripheral sub-region correspond to the same first converging lens 81, as shown in FIG. 8, the first converging lens 81 is a second convex lens, and an extension direction of the second convex lens is parallel to the second direction, that is, the same as an arrangement direction of the multiple photosensitive transistors 21 in the first peripheral sub-region. Since the extension direction of the first convex lens is the same as the arrangement direction of the multiple photosensitive transistors 21, all the photosensitive transistors 21 in the first peripheral sub-region may correspond to the same first converging lens 81.

The first convex lens/second convex lens may be a plano-convex lens, a biconvex lens, a concave-convex lens, or the like, and the type of the first converging lens 81 is not limited in the embodiment of the present disclosure.

In some embodiments, as shown in FIG. 1, the display panel further includes a protection layer 10 located on a side of the light converging layer 8 away from the substrate 1, and the protection layer 10 may be a glass cover plate, which can avoid damage to various film layers by external force due to the high strength of its material.

In some embodiments, a light shield layer 11 is provided between the protection layer 10 and the light converging layer 8, and a third light transmitting region 11a is formed in the light shield layer 11 at a position of the display region AA. In one example, the light shield layer 11 covers the peripheral region NA, and is configured to shield visible light and allow non-visible light within a preset wavelength range to pass through. It should be noted that the material color of the light shield layer 11 coincides with the color of the housing of the display panel in consideration of the appearance consistency of the display panel, and may be any one of gold, black, red, and the like. In another example, as shown in FIG. 1, the light shield layer 11 is further provided with a fourth light transmitting region 11b at a position thereof corresponding to the photosensitive region P of the photosensitive transistor 21, and a second light filter portion 111 is provided in the fourth light transmitting region 11b, and the second light filter portion 111 is configured to filter visible light.

In some embodiments, as shown in FIG. 1, the display panel further includes an encapsulation layer 4 and a first planarization layer 5, which are located on a side of the light emitting element layer 3 away from the substrate 1, and the encapsulation layer 4 is configured to encapsulate each light emitting element to prevent the light emitting element from being eroded by water and oxygen. The first planarization layer is located between the encapsulation layer 4 and the color filter layer 6, and is configured to planarize the structure of the display panel, and fills the portion between the encapsulation layer 4 and the color filter layer 6 to achieve the connection between the encapsulation layer 4 and the color filter layer 6, and the first planarization layer 5 may be made of an optical adhesive material.

The display panel further includes a second planarization layer 7 and an adhesive layer 9, wherein the second planarization layer 7 is positioned between the color filter layer 6 and the light converging layer 8. Since the first converging lens 81/second converging lens 82 in the light converging layer 8 is a convex lens and has an irregular shape, it is needed to form a converging lens on a planar surface in order to achieve a better light converging effect, so the second planarization layer 7 is provided below the light converging layer 8, and the material of the second planarization layer 7 and the material of the first planarization layer 5 may be the same. The adhesive layer 9 is positioned between the light converging layer 8 and the protection layer 10 and is used to achieve a connection between the light converging layer 8 and the protection layer 10.

It should also be noted that the surface(s) of a side of the first converging lens 81/second converging lens 82 away from the substrate 1 in the converging layer 8 in the embodiment of the present disclosure may be a convex and uneven surface, so the surface of the side of the first converging lens 81/second converging lens 82 away from the substrate 1 is filled with an organic material to meet the refractive index requirements of the converging layer 8, and maintain the planarization of various film layer structures in the display panel, which is beneficial to the preparation of subsequent film layers.

An embodiment of the present disclosure further provides a display apparatus, including a display panel described above.

The above display apparatus may be any product or component with a display function, such as electronic paper, a mobile phone, a tablet computer, a television, a display, a notebook computer, a digital photo frame, and a navigator, which is not limited in the present disclosure.

It may be understood that the above implementations are only exemplary implementations employed for the purpose of illustrating the principles of the present disclosure, however the present disclosure is not limited thereto. To those of ordinary skills in the art, various modifications and improvements may be made without departing from the essence and concept of the present disclosure, and these modifications and improvements are also considered to be within the scope of the present disclosure.

1. A display panel, comprising:
a substrate divided into a display region and a peripheral region surrounding the display region;
a drive function layer located on the substrate, wherein the drive function layer comprises: a photosensitive transistor located in the peripheral region and a plurality of pixel circuit transistors located in the display region;
wherein the peripheral region comprises a first N-well region surrounding a gate electrode of the photosensitive transistor, and the display region comprises a second N-well region overlapping with a gate electrode of a pixel circuit transistor, and an overlapping area of the second N-well region and the gate electrode of the pixel circuit transistor is larger than an overlapping area of the first N-well region and the gate electrode of the photosensitive transistor.

2. The display panel according to claim 1, wherein the photosensitive transistor further comprises a P-well region corresponding to the first N-well region, and the first N-well region surrounds the P-well region.

3. The display panel according to claim 2, wherein an area of the P-well region surrounded by the first N-well region is larger than a channel area of the pixel circuit transistor.

4. The display panel according to claim 1, wherein a size of the photosensitive transistor is larger than a size of the pixel circuit transistor.

5. The display panel according to claim 1, wherein the drive function layer further comprises a first deep N-well region located on a side of the first N-well region close to the substrate, and a thickness of the first deep N-well region is greater than a thickness of the first N-well region or the second N-well region.

6. The display panel according to claim 1, wherein the display panel further comprises a light emitting element layer located on a side of the drive function layer away from the substrate and located in the display region, the light emitting element layer comprises a plurality of light emitting elements, a light emitting element comprises: a first electrode, a light emitting layer, and a second electrode, the first electrode is electrically connected to a corresponding pixel circuit transistor;
the drive function layer further comprises: a voltage transmission wiring located in the peripheral region and electrically connected to the second electrode; and
the photosensitive transistor is located on a side of the voltage transmission wiring away from the display region.

7. The display panel according to claim 3, wherein an orthographic projection of any metal pattern located on a side of the photosensitive transistor away from the substrate on the photosensitive transistor does not overlap with a region where the first N-well region surrounds the P-well region.

8. The display panel according to claim 3, wherein the display panel further comprises:
a color filter layer located on a side of the light emitting element layer away from the substrate, wherein the color filter layer comprises a first light filter portion and a first black matrix that are located in the peripheral region;
at least one first light transmitting region corresponding to the photosensitive transistor is provided on the first black matrix, an orthographic projection of the first light transmitting region on the substrate overlaps with a region where the first N-well region of the corresponding photosensitive transistor surrounds the P-well region, the first light filter portion is located in the first light transmitting region, and the first light filter portion is configured to filter visible light.

9. The display panel according to claim 8, wherein the first light filter portion at least comprises a first filter pattern and a second filter pattern disposed in a stacked manner, the first filter pattern is configured to filter light in a wavelength range of a visible light wavelength range except a first wavelength range, the second filter pattern is configured to filter light in a wavelength range of the visible light wavelength range except a second wavelength range, and there is no overlap between the first wavelength range and the second wavelength range.

10. The display panel according to claim 9, wherein light of the first wavelength range is red light, and light of the second wavelength range is blue light;
the first light filter portion further comprises a third filter pattern stacked with the first filter pattern and the second filter pattern, and the third filter pattern is configured to be able to filter light of a color except green light among visible light.

11. The display panel according to claim 8, wherein the display panel further comprises:
a light converging layer located on a side of the color filter layer away from the substrate,
wherein the light converging layer comprises a first converging lens located in the peripheral region and corresponds to the photosensitive transistor, and a second converging lens located in the display region and corresponds to the light emitting element,
an orthographic projection of the first converging lens on the substrate covers a region where the first N-well region of the corresponding photosensitive transistor surrounds the P-well region;
an orthographic projection of the second converging lens on the substrate covers an orthographic projection of the light emitting layer of the corresponding light emitting element on the substrate; and
a focal length of the first converging lens is greater than a focal length of the second converging lens.

12. The display panel according to claim 11, wherein the peripheral region comprises: a first peripheral sub-region arranged in a first direction with the display region, and a plurality of photosensitive transistors arranged in a second direction are provided in the first peripheral sub-region;
the photosensitive transistors in the first peripheral sub-region are in one-to-one correspondence with the first converging lenses; or, all photosensitive transistors in the first peripheral sub-region correspond to a same first converging lens.

13. The display panel according to claim 12, wherein the photosensitive transistors in the first peripheral sub-region are in one-to-one correspondence with the first converging lenses, the first converging lens is a cylindrical lens, and an extension direction of a central axis of the cylindrical lens is perpendicular to a plane on which the substrate is located;
or,
the photosensitive transistors in the first peripheral sub-region are in one-to-one correspondence with the first converging lenses, the first converging lens is a first convex lens, and an extension direction of the first convex lens is parallel to the first direction;
or,
all photosensitive transistors in the first peripheral sub-region correspond to a same first converging lens, the first converging lens is a second convex lens, and an extension direction of the second convex lens is parallel to the second direction.

14. The display panel according to claim 11, wherein the display panel further comprises a protection layer and a light shield layer, the light shield layer is positioned between the protection layer and the light converging layer, and a third light transmitting region is formed in the light shield layer at a position of the display region;
the light shield layer covers the peripheral region and is configured to shield visible light and allow non-visible light within a preset wavelength range to pass through;
or,
the light shield layer is provided with a fourth light transmitting region in a position of the light shield layer corresponding to a position where the first N-well region of the photosensitive transistor surrounds the P-well region, and a second light filter portion is provided in the fourth light transmitting region, and the second light filter portion is configured to filter visible light.

15. A display apparatus, comprising the display panel according to claim 1.

16. The display panel according to claim 1, wherein the photosensitive transistor is configured to receive non-visible light in a preset wavelength range.

17. The display panel according to claim 1, wherein the photosensitive transistor comprises a bipolar junction transistor.

18. The display panel according to claim 8, wherein an orthographic projection of the first black matrix on the substrate does not overlap with an orthographic projection of a region where the first N-well region of the corresponding photosensitive transistor surrounds the P-well region on the substrate.

19. The display panel according to claim 9, wherein the color filter layer further comprises: a second black matrix and a plurality of color filter patterns located in the display region, the plurality of color filter patterns comprise: at least one fourth filter pattern, at least one fifth filter pattern, and at least one sixth filter pattern;
the fourth filter pattern is configured to be able to filter light of other colors other than red light in visible light, and the fourth filter pattern is made of a same material as the first filter pattern;
the fifth filter pattern is configured to be able to filter light of other colors other than blue light in visible light, and the fifth filter pattern is made of a same material as the second filter pattern; and
the sixth filter pattern is configured to be able to filter light of other colors other than green light in visible light, and the sixth filter pattern is made of a same material as the third filter pattern.

20. The display panel according to claim 19, wherein the second black matrix comprises a plurality of second light transmitting regions corresponding to the light emitting elements, an orthographic projection of a second light transmitting region on the substrate overlaps with an orthographic projection of a light emitting layer of a corresponding light emitting element on the substrate, and a corresponding color filter pattern is provided in the second light transmitting region.
